(19) United States
(12) Patent Application Publication
(10) Pub. No.: US 2023/0378933 A1
(43) Pub. Date: Nov. 23, 2023

(54) COMPOSITE SUBSTRATE, SURFACE ACOUSTIC WAVE ELEMENT, AND METHOD OF PRODUCING COMPOSITE SUBSTRATE

(71) Applicant: NGK INSULATORS, LTD., Nagoya-shi (JP)

(72) Inventors: Takeshi YAMAMOTO, Nagoya-shi (JP); Keiichiro ASAI, Nagoya-shi (JP); Naoki FUJITA, Nagoya-shi (JP)

(21) Appl. No.: 18/361,954

(22) Filed: Jul. 31, 2023

Related U.S. Application Data
(63) Continuation of application No. PCT/JP2021/048175, filed on Dec. 24, 2021.

(30) Foreign Application Priority Data
Feb. 5, 2021 (JP) 2021-017394

(51) Int. Cl. H03H 9/02; H03H 3/08

(52) U.S. Cl. CPC H03H 9/02866; H03H 3/08

(57) ABSTRACT

A composite substrate includes: a piezoelectric layer; and a reflective layer arranged on a back surface side of the piezoelectric layer, the reflective layer including a low-impedance layer containing silicon oxide and a high-impedance layer, wherein the piezoelectric layer has a modified layer formed in an end portion on the back surface side thereof, and wherein the low-impedance layer has a density of 2.15 g/cm³ or more.

### CROSS-REFERENCE TO RELATED APPLICATIONS

This application is a continuation under 35 U.S.C. 120 of International Application PCT/JP2021/048175 having the International Filing Date of Dec. 24, 2021, and having the benefit of the earlier filing date of Japanese Application No. 2021-017394, filed on Feb. 5, 2021. Each of the identified applications is fully incorporated herein by reference.

### BACKGROUND OF THE INVENTION

### Technical Field

The present invention relates to a composite substrate, a surface acoustic wave element, and a method of producing a composite substrate.

### Background Art

For example, a filter utilizing a surface acoustic wave (SAW filter) has been used in a communication device such as a cellular phone for extracting an electric signal having any appropriate frequency. The SAW filter has a structure in which an electrode or the like is formed on a composite substrate having a piezoelectric layer (see, for example, Patent Literature 1).

Incidentally, in recent years, in the field of an information communication device, the device has been required to support communication in a high-frequency band. In the SAW filter, the leakage of an elastic wave from the piezoelectric layer may occur. Meanwhile, the composite substrate has been required to have durability (e.g., durability at the time of its processing).

### CITATION LIST

### Patent Literature

[PTL 1] JP 2020-150488 A

### SUMMARY OF THE INVENTION

A primary object of the present invention is to provide a composite substrate that is excellent in durability while confining the energy of an elastic wave in its piezoelectric layer.

According to one embodiment of the present invention, there is provided a composite substrate, including: a piezoelectric layer; and a reflective layer arranged on a back surface side of the piezoelectric layer, the reflective layer including a low-impedance layer containing silicon oxide and a high-impedance layer, wherein the piezoelectric layer has a modified layer formed in an end portion on the back surface side thereof, and wherein the low-impedance layer has a density of 2.15 g/cm³ or more.

In one embodiment, the modified layer has a thickness of 0.3 nm or more.

In one embodiment, the modified layer has a thickness of 4.5 nm or less.

In one embodiment, the modified layer contains an amorphous substance.

In one embodiment, the modified layer has a silicon atom content of less than 10 atom %.

In one embodiment, the high-impedance layer contains at least one selected from: hafnium oxide; tantalum oxide; zirconium oxide; and aluminum oxide.

In one embodiment, the high-impedance layer and the low-impedance layer each have a thickness of from 0.01 μm to 1 μm.

In one embodiment, the high-impedance layer and the low-impedance layer are alternately laminated in the reflective layer.

In one embodiment, the composite substrate further includes a support substrate arranged on a back surface side of the reflective layer.

In one embodiment, the composite substrate further includes a joining layer arranged between the reflective layer and the support substrate.

According to another embodiment of the present invention, there is provided a surface acoustic wave element, including the above-mentioned composite substrate.

According to another aspect of the present invention, there is provided a method of producing a composite substrate. The method of producing a composite substrate includes: forming a modified layer in an end portion on a first main surface side of a piezoelectric substrate having a first main surface and a second main surface facing each other; forming a low-impedance layer containing silicon oxide and having a density of 2.15 g/cm³ or more on the first main surface side of the piezoelectric substrate; and forming a high-impedance layer on the first main surface side of the piezoelectric substrate having formed thereon the low-impedance layer.

In one embodiment, the modified layer has a thickness of 0.3 nm or more.

In one embodiment, the modified layer has a thickness of 4.5 nm or less.

In one embodiment, the production method further includes polishing a surface on a second main surface side of the piezoelectric substrate having formed thereon the low-impedance layer and the high-impedance layer.

### Advantageous Effects of Invention

According to the embodiment of the present invention, there can be provided the following composite substrate: the composite substrate includes the piezoelectric layer (piezoelectric substrate) and the reflective layer including the low-impedance layer having a predetermined density; and the modified layer is formed in the end portion of the piezoelectric layer (piezoelectric substrate), and hence the composite substrate is excellent in durability while confining the energy of an elastic wave in the piezoelectric layer.

### BRIEF DESCRIPTION OF THE DRAWINGS

FIG. 1 is a schematic sectional view for illustrating the schematic configuration of a composite substrate according to one embodiment of the present invention.

FIG. 2A is a view for illustrating an example of a production process for the composite substrate according to one embodiment.

FIG. 2B is a view subsequent to FIG. 2A.

FIG. 2C is a view subsequent to FIG. 2B.

FIG. 2D is a view subsequent to FIG. 2C.

FIG. 2E is a view subsequent to FIG. 2D.

FIG. 3 is a sectional TEM image of a composite substrate (first silicon oxide layer) of Example 2.

FIG. 4 is a sectional TEM image of a composite substrate (first silicon oxide layer) of Comparative Example 5.

### DESCRIPTION OF EMBODIMENTS

Embodiments of the present invention are described below. However, the present invention is not limited to these embodiments.

A. Composite Substrate

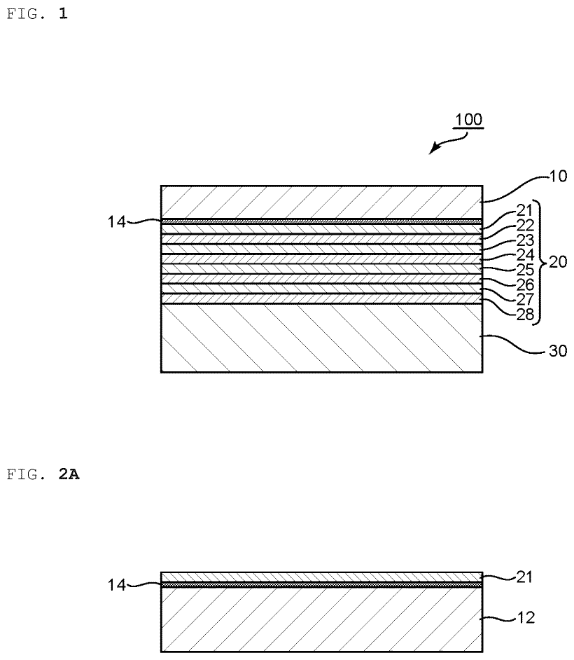

FIG. 1 is a schematic sectional view for illustrating the schematic configuration of a composite substrate according to one embodiment of the present invention. A composite substrate 100 includes a piezoelectric layer 10, a reflective layer 20, and a support substrate 30 in the stated order. A modified layer 14 is formed in an end portion on the side of the piezoelectric layer 10 on which the reflective layer 20 is arranged. The formation of such layer can provide a composite substrate excellent in durability. The reflective layer 20 includes a high-impedance layer having a relatively high acoustic impedance and a low-impedance layer having a relatively low acoustic impedance. The reflective layer 20 is a laminate of a plurality of impedance layers, and for example, the low-impedance layer and the high-impedance layer are alternately laminated. In the illustrated example, the reflective layer 20 includes a low-impedance layer 21, a high-impedance layer 22, a low-impedance layer 23, a high-impedance layer 24, a low-impedance layer 25, a high-impedance layer 26, a low-impedance layer 27, and a high-impedance layer 28 in the stated order from the piezoelectric layer 10 side. The low-impedance layer 21 out of the respective layers of the reflective layer 20 is arranged on the side closest to the piezoelectric layer 10. The arrangement of the reflective layer 20 having such laminated structure can effectively confine the energy of an elastic wave to the piezoelectric layer 10 side. The low-impedance layer arranged on the side closest to the piezoelectric layer 10 is sometimes referred to as “first low-impedance layer.”

In the illustrated example, the reflective layer 20 is a laminate of a total of 8 layers, that is, the 4 high-impedance layers and the 4 low-impedance layers. However, the number of the impedance layers in the reflective layer is not limited thereto. Specifically, the reflective layer only needs to include at least one high-impedance layer and at least one low-impedance layer, the layers being different from each other in acoustic impedance. The reflective layer preferably has a multilayer structure including 4 or more layers.

The composite substrate 100 may further include any appropriate layer (not shown). The kinds, functions, number, combination, arrangement, and the like of such layers may be appropriately set in accordance with purposes. For example, the composite substrate 100 may include a joining layer arranged between the reflective layer 20 and the support substrate 30.

The composite substrate 100 may be produced in any appropriate shape. In one embodiment, the substrate may be produced in the form of a so-called wafer. The size of the composite substrate 100 may be appropriately set in accordance with purposes. For example, the diameter of the wafer is from 50 mm to 150 mm.

A-1. Piezoelectric Layer

Any appropriate piezoelectric material may be used as a material for forming the piezoelectric layer. A single crystal having the composition of LiAO₃ is preferably used as the piezoelectric material. Herein, A represents one or more kinds of elements selected from: niobium; and tantalum. Specifically, LiAO₃ may be lithium niobate (LiNbO₃), lithium tantalate (LiTaO₃), or a lithium niobate-lithium tantalate solid solution.

When the piezoelectric material is lithium tantalate, a layer whose normal direction is rotated about X-axis of the piezoelectric material, which is the direction in which a surface acoustic wave propagates, from Y-axis thereof to Z-axis thereof by from 123° to 133° (e.g., 128°) is preferably used as the piezoelectric layer from the viewpoint of reducing a propagation loss. When the piezoelectric material is lithium niobate, a layer whose normal direction is rotated about X-axis of the piezoelectric material, which is the direction in which a surface acoustic wave propagates, from Y-axis thereof to Z-axis thereof by from 96° to 114° (e.g., 110°) is preferably used as the piezoelectric layer from the viewpoint of reducing a propagation loss.

The thickness of the piezoelectric layer is, for example, 0.2 μm or more and 5 μm or less.

The modified layer includes, for example, an amorphous substance, and contains an element for forming the piezoelectric layer. As a specific example, when the piezoelectric layer includes lithium tantalate, the modified layer contains tantalum (Ta) and oxygen (O). In one embodiment, when the total of Ta, O, Si, and Ar in the modified layer is set to 100 atom %, the silicon atom (Si) content of the layer may be less than 10 atom %, or 5 atom % or less. The composition of the modified layer may be determined by energy dispersive X-ray analysis (EDX).

The thickness of the modified layer is, for example, 0.3 nm or more, preferably 0.5 nm or more. Meanwhile, the thickness of the modified layer is, for example, 4.5 nm or less, preferably 4 nm or less. Such thickness can achieve a higher Q-value.

A-2. Reflective Layer

As described above, the reflective layer includes the high-impedance layer and the low-impedance layer different from each other in acoustic impedance. The acoustic impedance of the high-impedance layer is relatively higher than the acoustic impedance of the low-impedance layer. Specifically, the acoustic impedance of a material for forming the high-impedance layer is higher than the acoustic impedance of a material for forming the low-impedance layer.

The plurality of high-impedance layers in the reflective layer may be identical to each other in configuration (e.g., material or thickness), or may be different from each other in configuration. Similarly, the plurality of low-impedance layers in the reflective layer may be identical to each other in configuration (e.g., material, thickness, or density), or may be different from each other in configuration.

Examples of the material for forming the high-impedance layer include hafnium oxide, tantalum oxide, zirconium oxide, and aluminum oxide. Of those, hafnium oxide is preferably used. The use of hafnium oxide can more effectively confine the energy of an elastic wave to the piezoelectric layer side.

The thickness of the high-impedance layer is, for example, from 0.01 μm to 1 μm, preferably from 20 nm to 500 nm, more preferably from 100 nm to 300 nm.

A typical example of the material for forming the low-impedance layer is silicon oxide. In one embodiment, the content of silicon oxide in the low-impedance layer is, for example, 97 wt % or more. The ratio (O/Si) of an oxygen atom in the low-impedance layer to a silicon atom therein is, for example, 1.85 or more and 2.05 or less. The composition of the low-impedance layer may be identified by Rutherford backscattering spectrometry (RBS). At the time of the spectrometry, a sample obtained by separately forming the low-impedance layer on any appropriate substrate under the same conditions may be used.

The thickness of the low-impedance layer is, for example, from 0.01 μm to 1 μm, preferably from 20 nm to 500 nm, more preferably from 100 nm to 300 nm.

The density of the low-impedance layer is 2.15 g/cm³ or more. When the low-impedance layer has such density, the energy of an elastic wave can be more effectively confined to the piezoelectric layer side. Specifically, the low-impedance layer having such density is a dense layer, and hence can be suppressed from causing a structural defect such as a void (nanopore). As a result, an excellent reflective layer can be obtained, and hence a high Q-value can be achieved. In addition, even when the layer is combined with the modified layer, a high Q-value can be secured. In addition, the fact that the low-impedance layer has such density can contribute to an improvement in adhesiveness of the layer with the piezoelectric layer. Specifically, in the formation of the first low-impedance layer that is dense, the modified layer is easily formed on its adjacent layer (substrate), and hence a composite substrate excellent in durability can be obtained. It has been generally conceived that a low-impedance layer having a low density and a low volume modulus of elasticity is desirably formed from the viewpoint of effectively confining the energy of the elastic wave to the piezoelectric layer side. However, the fact that the combination of the low-impedance layer having the above-mentioned density and the modified layer can simultaneously achieve a high Q-value and excellent durability is an unexpected excellent effect.

The density of the low-impedance layer may be 2.2 g/cm³ or more, 2.25 g/cm³ or more, or 2.3 g/cm³ or more. When the layer has such density, a composite substrate excellent in heat resistance can be obtained. For example, even when the composite substrate is subjected to processing in which heat at 200° C. or more is applied thereto, the occurrence of peeling in the composite substrate (specifically, peeling in the reflective layer) can be suppressed. A possible cause for such peeling is the activation of the movement of moisture taken in the impedance layer (typically, in the above-mentioned void) by the heating. The density of the low-impedance layer is, for example, 2.5 g/cm³ or less.

Although at least one low-impedance layer (e.g., the first low-impedance layer) in the reflective layer only needs to satisfy the above-mentioned density, all the low-impedance layers in the reflective layer each preferably satisfy the above-mentioned density.

The density of the impedance layer may be determined by X-ray reflectometry (XRR).

The impedance layers may be formed by any appropriate method. The layers may be formed by, for example, physical vapor deposition, such as sputtering or ion beam-assisted deposition (IAD), chemical vapor deposition, or an atomic layer deposition (ALD) method. Of those, IAD is preferably adopted. The adoption of the IAD results in the formation of a dense impedance layer, and hence can satisfactorily achieve the above-mentioned density. In addition, at the time of the formation of the first low-impedance layer, the modified layer can be satisfactorily formed on its adjacent layer (substrate). For example, a modified layer having a desired thickness can be formed.

A-3. Support Substrate

Any appropriate substrate may be used as the support substrate 30. The support substrate may include a single crystalline substance, or may include a polycrystalline substance. A material for forming the support substrate is preferably selected from: silicon; sialon; sapphire; cordierite; mullite; glass; quartz; crystal; and alumina.

The silicon may be single crystal silicon, polycrystalline silicon, or high resistance silicon.

Typically, the sialon is a ceramic obtained by sintering a mixture of silicon nitride and alumina, and has composition represented by, for example, Si_{6-w}Al_{w}O_{w}N_{8-w}. Specifically, the sialon has such composition that alumina is mixed into silicon nitride, and “w” in the formula represents the mixing ratio of alumina. “w” preferably represents 0.5 or more and 4.0 or less.

Typically, the sapphire is a single crystalline substance having the composition of Al₂O₃, and the alumina is a polycrystalline substance having the composition of Al₂O₃. The alumina is preferably translucent alumina.

Typically, the cordierite is a ceramic having the composition of 2MgO·2Al₂O₃·5SiO₂, and the mullite is a ceramic having composition in the range of from 3Al₂O₃·2SiO₂ to 2Al₂O₃·SiO₂.

The thermal expansion coefficient of the material for forming the support substrate is preferably smaller than the thermal expansion coefficient of the material for forming the piezoelectric layer. Such support substrate can suppress changes in shape and size of the piezoelectric layer at the time of a temperature change, and hence can suppress, for example, a change in frequency characteristic of a surface acoustic wave element to be obtained.

Any appropriate thickness may be adopted as the thickness of the support substrate. The thickness of the support substrate is, for example, from 100 μm to 1,000 μm.

A-4. Joining Layer

As described above, the composite substrate may include the joining layer. A material for forming the joining layer is, for example, a silicon oxide, silicon, tantalum oxide, niobium oxide, aluminum oxide, titanium oxide, or hafnium oxide. The thickness of the joining layer is, for example, from 0.005 μm to 1 μm.

The joining layer may be formed by any appropriate method. Specifically, the layer may be formed by the same method as the above-mentioned method of forming the impedance layers.

A-5. Production Method

A method of producing a composite substrate according to one embodiment of the present invention includes: forming a modified layer in an end portion on a first main surface side of a piezoelectric substrate having a first main surface and a second main surface facing each other; forming a low-impedance layer containing silicon oxide on the first main surface side of the piezoelectric substrate; and forming a high-impedance layer on the first main surface side of the piezoelectric substrate having formed thereon the low-impedance layer.

Specifically, the composite substrate may be obtained by: forming the modified layer in the piezoelectric substrate; sequentially forming the impedance layers for forming the reflective layer; and directly joining the piezoelectric substrate having formed thereon the reflective layer and the support substrate to each other. The thickness of the piezoelectric substrate is, for example, 200 μm or more and 1,000 μm or less.

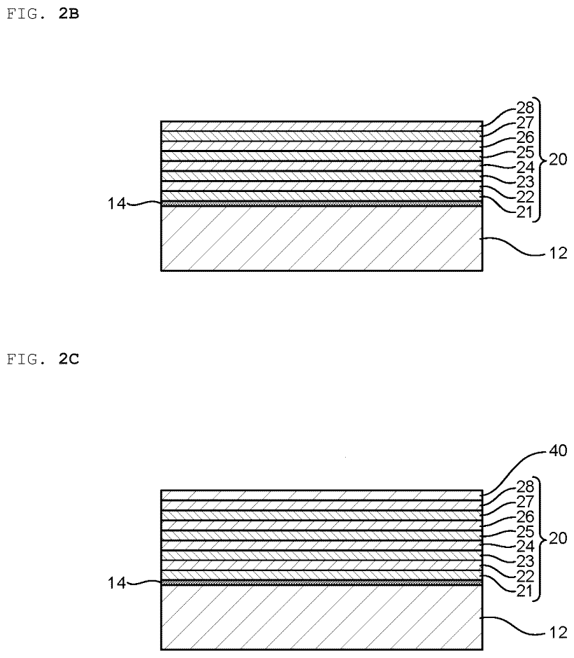

FIG. 2A to FIG. 2E are each a view for illustrating an example of a production process for the composite substrate according to one embodiment. FIG. 2A is an illustration of a state in which the modified layer 14 is formed in an end portion (upper end portion) on the first main surface side of a piezoelectric substrate 12 having a first main surface and a second main surface facing each other, and the formation of the first low-impedance layer 21 on the modified layer 14 is completed. The modified layer 14 is preferably a layer formed by modifying the upper end portion of the piezoelectric substrate 12. Such modified layer is formed by, for example, depositing a material for forming the first low-impedance layer 21 from the vapor onto the piezoelectric substrate 12 while applying energy (e.g., ion energy) to the layer-forming material. Specifically, at the time of the formation of the first low-impedance layer 21, atoms for forming the first low-impedance layer 21 may be shot into the upper end portion of the piezoelectric substrate 12 to form the modified layer 14.

After the formation of the low-impedance layer 21, the impedance layers 22 to 28 are sequentially formed on the low-impedance layer 21 to form the reflective layer 20 as illustrated in FIG. 2B. The respective impedance layers 21 to 28 may be formed by the same method under the same conditions, or may be formed by different methods under different conditions.

FIG. 2C is an illustration of a state in which a joining layer 40 is formed on the reflective layer 20, and FIG. 2D is an illustration of a step of directly joining the piezoelectric substrate 12 having formed thereon the reflective layer 20 and the joining layer 40, and the support substrate 30. At the time of the direct joining, the joining surfaces of the layer and the substrate are preferably activated by any appropriate activation treatment. The direct joining is performed by, for example, activating a surface 40a of the joining layer 40, activating a surface 30a of the support substrate 30, then bringing the activated surface of the joining layer 40 and the activated surface of the support substrate 30 into contact with each other, and pressurizing the resultant. Thus, a composite substrate 110 illustrated in FIG. 2E is obtained.

A surface (lower surface) 12a on the second main surface side of the piezoelectric substrate 12 of the resultant composite substrate 110 is typically subjected to processing, such as grinding or polishing, so that a piezoelectric layer having the above-mentioned desired thickness may be obtained. The formation of the modified layer 14 can make the composite substrate 110 excellent in durability. For example, the substrate can be excellent in durability at the time of its processing, such as grinding or polishing. Specifically, the occurrence of peeling in the composite substrate (specifically, peeling near a boundary between the piezoelectric substrate 12 and the low-impedance layer 21) due to the processing, such as grinding or polishing, can be suppressed. As a result, there can be obtained a composite substrate, which is free of any peeling and is hence excellent in quality.

The surface of each layer (specifically, the piezoelectric layer, the piezoelectric substrate, the reflective layer, the support substrate, or the joining layer) is preferably a flat surface. Specifically, the arithmetic average roughness Ra of the surface of each layer is preferably 1 nm or less, more preferably 0.3 nm or less. A method of flattening the surface of each layer is, for example, mirror polishing, lap polishing, or chemical-mechanical polishing (CMP).

At the time of the film formation and the joining described above, the surface of each layer is preferably washed for, for example, removing the residue of a polishing agent, a work-affected layer, or the like. A method for the washing is, for example, wet washing, dry washing, or scrub washing. Of those, scrub washing is preferred because the surface can be simply and efficiently washed. A specific example of the scrub washing is a method including washing the surface in a scrub washing machine with a detergent (e.g., a SUNWASH series manufactured by Lion Corporation) and then with a solvent (e.g., a mixed solution of acetone and isopropyl alcohol (IPA)).

The activation treatment is typically performed by irradiating the joining surface with a neutralized beam. The activation treatment is preferably performed by generating the neutralized beam with an apparatus such as an apparatus described in JP 2014-086400 A, and irradiating the joining surface with the beam. Specifically, a saddle-field fast atomic beam source is used as a beam source, and an inert gas, such as argon or nitrogen, is introduced into the chamber of the apparatus, followed by the application of a high voltage from the DC power source thereof to an electrode thereof. Thus, a saddle-field electric field is generated between the electrode (positive electrode) and the casing (negative electrode) thereof to cause electron motion, to thereby generate the beams of an atom and an ion by the inert gas. Of the beams that have reached the grid of the fast atomic beam source, an ion beam is neutralized by the grid, and hence the beam of a neutral atom is emitted from the fast atomic beam source. The voltage at the time of the activation treatment by the beam irradiation is preferably set to from 0.5 kV to 2.0 kV, and a current at the time of the activation treatment by the beam irradiation is preferably set to from 50 mA to 200 mA.

The joining surfaces are preferably brought into contact with each other and pressurized in a vacuum atmosphere. A temperature at this time is typically normal temperature. Specifically, the temperature is preferably 20° C. or more and 40° C. or less, more preferably 25° C. or more and 30° C. or less. A pressure to be applied is preferably from 100 N to 20,000 N.

B. Surface Acoustic Wave Element

A surface acoustic wave element according to the present invention includes the above-mentioned composite substrate. The composite substrate can achieve a high Q-value. In addition, the composite substrate is excellent in durability. Accordingly, the surface acoustic wave element obtained by, for example, subjecting the composite substrate to processing, such as the formation of an electrode or the like, or cutting, is suppressed from causing peeling, cracking, or the like, and hence can be excellent in quality. Such surface acoustic wave element is suitably used as a SAW filter in a communication device such as a cellular phone.

### EXAMPLES

Now, the present invention is specifically described by way of Examples. However, the present invention is not limited by these Examples.

### Example 1

A lithium tantalate (LT) substrate having an orientation flat (OF) portion, and having a diameter of 4 inches and a thickness of 250 μm (such a 128° Y-cut X-propagation LT substrate that the direction in which a surface acoustic wave (SAW) propagated was represented by X, the substrate being a rotated Y-cut plate having a cut-out angle of 128°) was prepared. The surface of the LT substrate was subjected to mirror polishing so as to have an arithmetic average roughness Ra of 0.3 nm. Herein, the arithmetic average roughness Ra is a value measured with an atomic force microscope (AFM) in a field of view measuring 10 μm by 10 μm.

Next, a first silicon oxide layer (thickness: 150 nm) was formed on the polished surface of the LT substrate by an IAD method. Specifically, the layer was formed at a layer formation rate of 1 nm/s by irradiating fused quartz with an electron beam at a vacuum degree of 2×10−2 Pa in a stream of oxygen and argon gases (flow rate ratio: oxygen/argon=2.0). After that, a hafnium oxide layer (thickness: 200 nm) and a silicon oxide layer (thickness: 150 nm) were sequentially formed. Specifically, the layers were each formed at a layer formation rate of 0.5 nm/s by irradiating a hafnium oxide target or a silicon oxide target with an electron beam at a vacuum degree of 2×10−2 Pa in a stream of oxygen and argon gases (flow rate ratio: oxygen/argon=2.2). Thus, such a reflective layer as illustrated in FIG. 1 was formed.

Next, a silicon oxide layer (thickness: from 80 nm to 190 nm, arithmetic average roughness Ra: from 0.2 nm to 0.6 nm) was formed on the reflective layer. Specifically, the layer was formed by a DC sputtering method with a boron-doped Si target. In addition, an oxygen gas was introduced as an oxygen source. At this time, the total pressure and oxygen partial pressure of an atmosphere in the chamber of the apparatus were regulated by regulating the amount of the oxygen gas to be introduced. After that, the surface of the silicon oxide layer was subjected to chemical-mechanical polishing (CMP). Thus, a joining layer (thickness: 50 nm, arithmetic average roughness Ra: from 0.08 nm to 0.4 nm) was formed.

A support substrate made of silicon having an OF portion, and having a diameter of 4 inches and a thickness of 500 μm was prepared. The surface of the support substrate was subjected to chemical-mechanical polishing (CMP), and had an arithmetic average roughness Ra of 0.2 nm.

Next, the LT substrate and the support substrate were directly joined. Specifically, the surface (joining layer side) of the LT substrate and the surface of the support substrate were washed, and then both the substrates were loaded into the vacuum chamber of the apparatus, followed by its evacuation to a vacuum of the order of 10⁻⁶ Pa. After that, the surfaces of both the substrates were irradiated with fast atomic beams (acceleration voltage: 1 kV, Ar flow rate: 27 sccm) for 120 seconds. After the irradiation, the beam-irradiated surfaces of both the substrates were superimposed on each other, and both the substrates were joined by being pressurized at 10,000 N for 2 minutes. After that, the resultant joined body was heated at 100° C. for 20 hours.

Next, the back surface of the LT substrate of the joined body (composite substrate) was ground and polished so that the thickness of the LT substrate was reduced from its initial value, that is, 250 μm to 0.5 μm. Thus, a composite substrate including a piezoelectric layer having a thickness of 0.5 μm was obtained.

### Examples 2 to 6 and Comparative Examples 1 to 5

Composite substrates were each obtained in the same manner as in Example 1 except that the conditions under which the first silicon oxide layer (thickness: 150 nm) was formed by the IAD method were changed.

<Evaluation>

The resultant composite substrates were each subjected to the following evaluations. The evaluation results are summarized in Table 1.

### 1. Recognition of Modified Layer

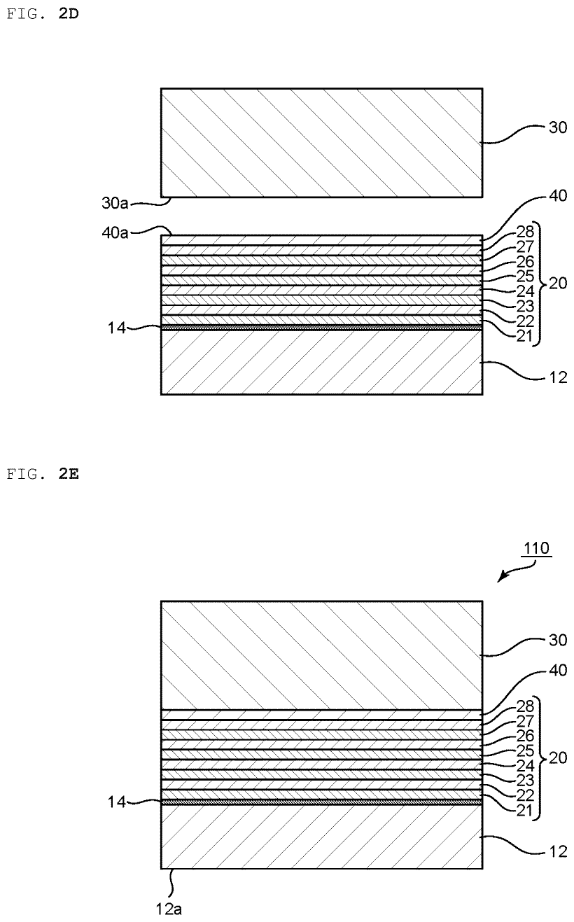

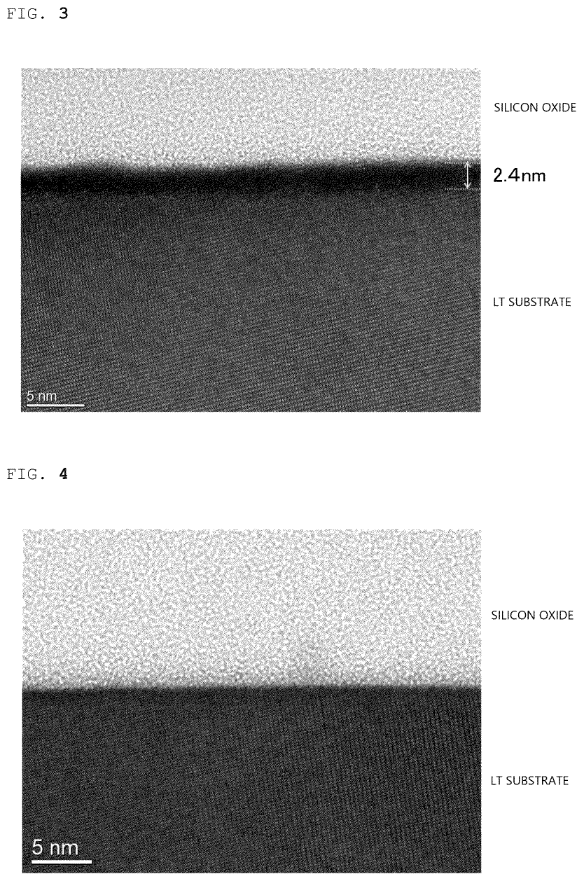

The presence or absence of the formation of a modified layer of the LT substrate was recognized through observation with a field emission transmission electron microscope (“JEM-F200” manufactured by JEOL Ltd.) (TEM observation). A sample for TEM observation was produced by a FIB method, and the TEM observation was performed at an acceleration voltage of 200 kV and a magnification of 5,400,000. As examples, a sectional TEM image of the composite substrate (first silicon oxide layer) of Example 2 is shown in FIG. 3, and a sectional TEM image of the composite substrate (first silicon oxide layer) of Comparative Example 5 is shown in FIG. 4.

When the modified layer was observed, its thickness was measured. Specifically, a region in the resultant TEM image from the site at which the crystal structure of the LT substrate was able to be recognized to a site having a tone intermediate between the tone of the silicon oxide layer and the tone of the modified layer was adopted as the modified layer, and its thickness was measured. The measurement was performed at the site having the largest thickness in the resultant TEM image.

### 2. Measurement of Density

The density of the silicon oxide layer of each of the composite substrates was determined by X-ray reflectometry (XRR).

A measurement sample obtained as described below was analyzed with a fully automatic multipurpose X-ray diffractometer (“SmartLab” manufactured by Rigaku Corporation) under the conditions of: an incident X-ray wavelength of 0.15418 nm (CuKα ray); X-ray outputs of 45 kV and 200 mA; a measurement range (angle formed by an X-ray with respect to the surface of the sample) of from 0.0° to 4.0°; and a measurement step of 0.01°.

A product obtained by separately forming the silicon oxide layer on a substrate (e.g., a silicon substrate, a lithium niobate substrate, or a lithium tantalate substrate) under the same conditions was used as the measurement sample.

The resultant analysis model was divided into three sections, that is, the substrate, the modified layer, and the silicon oxide layer, and the sections were analyzed, followed by the determination of the density of the silicon oxide layer. When the thickness of the silicon oxide layer was large, or when the thickness of the modified layer was difficult to analyze, the analysis model was divided into two sections, that is, the substrate and the silicon oxide layer, and the density of the silicon oxide layer was determined from the critical angle of a measured profile between the sections.

### 3. Measurement of Q-Value

The frequency characteristic of a surface acoustic wave element obtained by forming a comb electrode on the surface of the piezoelectric layer of each of the composite substrates was measured with a network analyzer. A resonance frequency fr and its half-width Δfr were determined from the resultant frequency characteristic, and the Q-value was calculated from the ratio “fr/Δfr”.

### 4. Durability

The durability of each of the composite substrates of Examples and Comparative Examples was evaluated by observing the composite substrate with a microscope before and after grinding and polishing the back surface of the LT substrate thereof to recognize whether or not peeling occurred in the composite substrate.

TABLE 1

| | | Density of | | Durability |
|---|---|---|---|---|
| | Thickness | first silicon | | Peeling at |
| | of modified | oxide layer | Q-value | time of |
| | layer (nm) | (g/cm³) | (%) | polishing |
| Example 1 | 0.5 | 2.16 | 143 | Absent |
| Example 2 | 2.4 | 2.17 | 118 | Absent |
| Example 3 | 3.8 | 2.15 | 100 | Absent |
| Example 4 | 1.3 | 2.32 | 145 | Absent |
| Example 5 | 2.6 | 2.31 | 120 | Absent |
| Example 6 | 3.4 | 2.33 | 102 | Absent |
| Comparative | — | 2.12 | 95 | Present |
| Example 1 | | | | |
| Comparative | 1.2 | 2.13 | 86 | Absent |
| Example 2 | | | | |
| Comparative | 3.1 | 2.14 | 70 | Absent |
| Example 3 | | | | |
| Comparative | 4.3 | 2.12 | 61 | Absent |
| Example 4 | | | | |
| Comparative | — | 2.29 | 155 | Present |
| Example 5 | | | | |

In each of Comparative Example 1 and Comparative Example 5 in which no modified layers were recognized, it was recognized that the peeling occurred owing to the grinding and polishing of the back surface of the LT substrate. Specifically, it was recognized that the peeling occurred near a boundary between the LT substrate and the first silicon oxide layer (at the initial stage of the formation of the first silicon oxide layer on the LT substrate).

It is found that in each of Examples, a high Q-value is obtained even under a state in which the modified layer is present.

The analysis of each of the modified layers by energy dispersive X-ray analysis (EDX) detected Ta and O, and a trace amount of Ar.

A sample for measurement (sample in which the silicon oxide layer was formed on the LT substrate) was produced under the same conditions as those of Example 2, and the composition of its modified layer was analyzed through STEM-EDX observation with an atomic-resolution analytical electron microscope (manufactured by JEOL Ltd., JEM-ARM 200F Dual-X) and an energy dispersive X-ray analyzer (manufactured by JEOL Ltd., JED-2300) at an acceleration voltage of 200 kV and a beam spot size of about 0.2 nmΦ. Specifically, line analysis was performed in the thickness direction of the modified layer, and an analysis site was set within a range having a thickness corresponding to 25% of the thickness of the modified layer from a center in the thickness direction of the modified layer toward each of the first silicon oxide layer and the LT substrate. Si contents were measured at intervals of about 0.2 nm in the thickness direction, and the average of the results was calculated. As a result, the Si content when the total of Ta, O, Si, and Ar was set to 100 atom % was 7.0 atom % or less.

### INDUSTRIAL APPLICABILITY

The composite substrate according to one embodiment of the present invention may be suitably used in a surface acoustic wave element.

What is claimed is:

1. A composite substrate, comprising:
a piezoelectric layer; and
a reflective layer arranged on a back surface side of the piezoelectric layer, the reflective layer including a low-impedance layer containing silicon oxide and a high-impedance layer,
wherein the piezoelectric layer has a modified layer formed in an end portion on the back surface side thereof, and
wherein the low-impedance layer has a density of 2.15 g/cm³ or more.

2. The composite substrate according to claim 1, wherein the modified layer has a thickness of 0.3 nm or more.

3. The composite substrate according to claim 1, wherein the modified layer has a thickness of 4.5 nm or less.

4. The composite substrate according to claim 1, wherein the modified layer contains an amorphous substance.

5. The composite substrate according to claim 1, wherein the modified layer has a silicon atom content of less than 10 atom %.

6. The composite substrate according to claim 1, wherein the high-impedance layer contains at least one selected from: hafnium oxide; tantalum oxide; zirconium oxide; and aluminum oxide.

7. The composite substrate according to claim 1, wherein the high-impedance layer and the low-impedance layer each have a thickness of from 0.01 μm to 1 μm.

8. The composite substrate according to claim 1, wherein the high-impedance layer and the low-impedance layer are alternately laminated in the reflective layer.

9. The composite substrate according to claim 1, further comprising a support substrate arranged on a back surface side of the reflective layer.

10. The composite substrate according to claim 9, further comprising a joining layer arranged between the reflective layer and the support substrate.

11. A surface acoustic wave element, comprising the composite substrate of claim 1.

12. A method of producing a composite substrate, comprising:
forming a modified layer in an end portion on a first main surface side of a piezoelectric substrate having a first main surface and a second main surface facing each other;
forming a low-impedance layer containing silicon oxide and having a density of 2.15 g/cm³ or more on the first main surface side of the piezoelectric substrate; and
forming a high-impedance layer on the first main surface side of the piezoelectric substrate having formed thereon the low-impedance layer.

13. The production method according to claim 12, wherein the modified layer has a thickness of 0.3 nm or more.

14. The production method according to claim 12, wherein the modified layer has a thickness of 4.5 nm or less.

15. The production method according to claim 12, further comprising polishing a surface on a second main surface side of the piezoelectric substrate having formed thereon the low-impedance layer and the high-impedance layer.
